(19) United States
(12) Patent Application Publication
(10) Pub. No.: US 2005/0285145 A1
(43) Pub. Date: Dec. 29, 2005

(54) Web image transfer system using LED based lighting systems

(76) Inventor: Nadarajah Narendran, Clifton Park, NY (US)

Correspondence Address: RATNERPRESTIA, P O BOX 980, VALLEY FORGE, PA, 19482-0980, US

(21) Appl. No.: 10/874,930

(22) Filed: Jun. 23, 2004

(51) Int. Cl. H01L 29/739

(52) U.S. Cl. 257/200

(57) ABSTRACT

A system for transmitting a color image over a network. The system has a light source, a first reference color chart exhibiting a first spectral response, a camera capturing an image of the first reference color chart for transmission to a receiver, and a receiver for displaying the image. The displayed image exhibits a second spectral response. The system also has a second reference color generator replicating the first spectral response, a comparator for generating a signal responsive to a difference between the replicated first spectral response and the second spectral response, and an adjuster for adjusting the displayed image responsive to the signal.

### FIELD OF THE INVENTION

The present invention relates generally to a light emitting diode (LED) based lighting system. More particularly, the invention relates to an LED based lighting system for web image transfer applications between the original object and the final image.

### BACKGROUND OF THE INVENTION

According to the Census Bureau report by US Department of Commerce, retail e-commerce sales in first quarter 2003 were $11.9 billion, up 25.9 percent from first quarter 2002. Experts in the industry believe that web merchandising will grow rapidly and have a major impact in the retail segment in the near future. Presently, almost all large retailers in the United States have web sites for selling their products over the Internet.

Generally, buyers rely on the image displayed on their computer terminals to make the purchase decision. If the product is not attractive then the decision is negative. Also, if the product they receive does not look like what they saw on their computer screen they are disappointed and may return the product. Either way, the retailer experiences lost revenue and unreimbursable expense. To avoid such problems, accurate color reproduction is one of the most important factors, especially for garments and other personal effects. Often, different products in a display or in an advertisement appear differently under two different types of light sources.

Performing medical diagnosis, assessment, and surgery from a remote location via the Internet is no longer science fiction. Advances in communications technologies now allow doctors and surgeons to remotely diagnose medical conditions and even to perform telesurgery. Success of these diagnoses or surgeries largely depends on the quality of the image viewed by the expert doctor or surgeon. In this regard, color appearance, especially in the red region of the visible spectrum, is one of the most important factors, since most tissues, organs, and skin are red in color and may have different shades of red.

Color gamut is the total range of colors reproduced by a color model or a device. It is the entire range of perceived color that may be obtained under specified conditions. One of the major problems in transferring digital images among devices and reproducing accurate color is gamut mismatch. The gamut area varies significantly among different display units.

Using light sources that have nearly equal energy at all wavelengths of the visible spectrum (for example, sunlight exhibits an equal energy spectrum) tends to provide better color rendering properties. Recently, Andreas Wenger and others presented a method for improving color matching of digital images by using a solid state lighting system that had multiple colored light emitting diodes (LEDs) to create the equal energy spectrum. Wenger A., et al. “Optimizing Color Matching in a Lighting Reproduction System for Complex Subject and Illuminant Spectra,” Euro Graphics Symposium on Rendering: 14^{th} Eurographics Workshop on Rendering, pp. 249-259 (2003). Other studies have also shown that color rendering properties of LED lighting systems can be improved with multi-spectral approaches. A. Zukauskas, et al., “Introduction to Solid State Lighting,” John Wiley and Sons (2002); Y. Li, et al., “Performance characteristics of white light sources consisting of multiple light-emitting diodes,” SPIE Proceedings, Vol. 5187. Although all of these studies have looked at improving the color rendering properties, they still cannot guarantee color accuracy.

Various illumination devices and methods have been developed.

U.S. Pat. No. 5,852,675 issued to Matsuo et al. is directed to a method of color correction for use at the time of recording color images of human skin. The method records images of a color chart along with an object. The recorded images are digitized and stored as digital data. The stored digital data are displayed on a display screen. The color value of at least two colors on the color chart are read on the display. A correcting value for each of the colors is computed based on the digital data of the color value of the read color chart and the target values in the corresponding zone in the color chart. The stored digital data are corrected bit-by-bit with the computed correcting value to store again in the storage device. Although this method is suitable for matching pictures taken at different times by correcting the color of static pictures, it is not suitable for correcting colors of images that change rapidly.

U.S. Pat. No. 5,712,535 issued to Ogawa is directed to a fill-in light apparatus which can match the color temperature of the strobe light of a still video camera to the color temperature of ambient light, upon strobe emission. The primary object of the invention is to provide a fill-in light (auxiliary light) emitting apparatus in which object colors can be faithfully reproduced in an image taken using the fill-in light. The invention uses a plurality of light emission tubes of differing light emission color temperatures, and having a strobe light emission control apparatus in which the color temperature of light projected onto a photographing object from the strobe light emission apparatus is matched to the color temperature of illumination in the photographing object by time-sharing of the light emission time of the respective light emission tubes to obtain an optimal exposure.

U.S. Pat. No. 6,149,283 issued to Conway et al. is directed to an LED lamp with reflector and multicolor adjuster. As shown in FIGS. 1 and 2, the lamp includes a set of three color adjusters 18, 20, 22 to independently adjust the light output of the three different color LEDs or LED sets 19, 21, 23, along with a concave reflector 30. The system uses the color LEDs as the light source and mixes different colors to create white light or any other color that is desired or required with a uniform distribution. The color of the output light can be easily customized and changed by using the color adjusters 18, 20, 22. The LEDs may be red, green, and blue. The LEDs are individually powered either with all equal power to produce white light or with power which is biased toward one color or the other to produce red, green, or blue light. Any combination of hues can be produced either manually or by providing suitable circuits to automate the operation of the color adjusters 18, 20, 22.

U.S. Pat. No. 6,379,022 issued to Amerson et al. is directed to an auxiliary illuminating device having adjustable color temperature. As shown in FIG. 4, the array is made with three different color LEDs. Two of the three colors are blue 402 and green 404. The third color is either red or amber. For the array of LEDs to simulate the color temperature of the ambient light, the type of illumination to be matched must be known. One way is for the user to select the type of lighting from a list of choices. Another way is for the camera or an auxiliary device to measure the current light in the scene and determine the type of illumination. Once the type of illumination to be matched has been determined, the amount of light coming from each set of color LEDs is adjusted such that the total amount of light coming from the LED array is a calorimetric match to the ambient illumination source.

U.S. Pat. No. 6,488,390 issued to Lebens et al. is directed to a color-adjusted camera light and method. FIG. 1 illustrates an LED flashlight 100 having a case 110, a battery 120, a power supply and control circuit 130, and a plurality of LEDs 150. Feedback 160 measures the light output of LEDs 150 and provides a signal that allows PSCC 130 to adjust the light output to a desired level. In one embodiment, flashlight 100 is used in conjunction with a portable video camcorder or other video camera. Feedback 160 measures the overall ambient light and provides a signal that allows generation of flashlight pulses to compensate for lack of light, in order to provide optimal lighting for the video camera. In the embodiment of FIG. 5, the controlled LED light source is integrated into a hand-held camcorder 500. Feedback circuit 160 measures the color balance of the video output signal and provides separate feedback intensity control for each of a plurality of separate groups of color LEDs.

U.S. patent application Publication No. 2003/0095406 filed by Lebens et al. is directed to a method and apparatus for a pulsed LED illumination source. As shown in the figures, feedback circuit 160 controls pulse width and/or frequency as a function of parameters such as battery voltage, LED light output intensity, power dissipation or device temperature, or LED color spectrum output. Feedback circuit 160 measures the video output signal from the camera and provides a feedback signal 260 that allows adjustment of the light output of LEDs 150 in order to optimize the video signal. In one such embodiment, the video camera circuit provides pulse sync signal 170 in order to synchronize the light output to the video light gathering time windows. In another embodiment, feedback circuit 160 measures the color balance of the video output signal and provides separate feedback intensity control for each of a plurality of separate groups of color LEDs, for example, red, green, and blue.

U.S. Pat. No. 5,436,535 issued to Yang relates to a multi-color light source, including a plurality of LEDs of different colors or including color filters in combination with uni-color LEDs. The LEDs may be arranged in different geometrical patterns.

U.S. Pat. No. 5,803,579 issued to Turnbull et al. discloses a high-efficiency illuminator assembly projecting white illumination and having LEDs of two types whose emissions when energized have hues which are complementary to one another and additively combine to form illumination with a metameric white color. U.S. Pat. No. 5,851,063 issued to Doughty et al. discloses a system using at least three multi-colored LEDs for use as a white light source for general illumination purposes. U.S. Pat. No. 6,056,420 issued to Wilson et al. discloses an illuminator for illuminating a work area in a darkroom or with scientific instrumentation using several light emitting diodes arranged in a regular array. U.S. Pat. No. 6,095,661 issued to Lebens et al. discloses a method and apparatus for controlling and powering a solid state light source such as a light-emitting diode for a portable battery-powered flashlight. U.S. Pat. No. 6,474,836 issued to Konagaya discloses a light source formed by connecting a plurality of light emitting elements to predetermined positions formed in advance on a substrate and to an original reading device which irradiates light onto an original and reads the transmitted image by light converting elements. U.S. Pat. No. 6,523,976 issued to Turnbull et al. discloses an illuminator assembly having a plurality of LEDs on a vehicular support member, the light emitting diodes having complementary hues.

U.S. patent application Publication No. 2002/0044435 filed by Pohlert et al. is related to lighting systems that may be used in film, television, and close-up photography. It is directed to a wide area lighting effects system. As shown in FIG. 1, the lighting frame 102 may be generally ring-shaped and may define a central hole 103 through which camera 140 can view. The lighting frame 202 of FIG. 2 may include a mounting assembly receptor 220 for receiving a mounting assembly 230, and an electrical socket 215 for receiving a cable 213 providing electrical power to lamps 205 from a power source 210. A power controller 212 is preferably interposed between the power source 210 and the electrical socket 215 for providing various lighting effect functions such as dimming, strobing, selective activating, pulsing, or combinations of these functions. Each of the lamp segments 306 preferably comprises a plurality of low power lamps 305. The low power lamps are preferably solid state in nature and may comprise light emitting diodes, light emitting crystals, or other low-power, versatile light sources. FIG. 17 illustrates an opaque, ring-shaped cover 1701 which may be used in connection with the lighting frame assembly and may be used as a color filter for the LEDs.

U.S. patent application Publication No. 2003/0072156 filed by Pohlert et al. is related to a lighting apparatus that may be used in film, television, and photography using LEDs on a panel or frame. The panel or frame may have an opening through which a camera can view. The lamp elements may be electronically controlled so as to provide differing intensity levels collectively, individually, or in designated groups. They may be strobed, dimmed, or otherwise controlled according to manual or programmable patterns.

U.S. patent application Publication No. 2003/0156425 filed by Turnbull et al. discloses white-light emitting assemblies utilizing a solid state light source such as a light emitting diode.

U.S. Pat. No. 6,672,734 issued to Lammers discloses a backlight system having a light-emitting panel 1 provided with a sensor for measuring the optical properties of the light which is emitted by light source 6, 7, which may be a plurality of blue, green and red LEDs. The sensor is coupled to control electronics for adapting the luminous flux of the light source 6, 7. By means of the sensor and the control electronics, a feedback mechanism can be formed for influencing the quality and the quantity of the light coupled-out of the panel 1.

None of the devices described above disclose a system that can accurately transfer a color image.

To overcome the shortcomings of prior web image transfer systems, a new system that may use solid state light sources is provided. An object of the present invention is to provide good color match between the original object and the final image to be used in applications such as, but not limited to, web merchandising, remote diagnostic, surgical and health assessment of humans, and structures. A related object is to create a system and method to compensate for variations in color and intensity of a transmitted image. Another object is to provide a solid state light source, based tunable light source such as an LED, with feedback control rather than a static light source at the location where the original object is being videographed or photographed.

It is still another object of the present invention to use a video terminal that uses an identical, substantially similar, or equivalent tunable light source as the light source used to illuminate the original object, and to adjust the colors of the display monitor so that the displayed image appears correctly in terms of color.

### SUMMARY OF THE INVENTION

To achieve these and other objects, and in view of its purposes, the present invention provides a system for transmitting a color image over a network. The system has a light source, a first reference color means exhibiting a first spectral response, a camera capturing an image of the first reference color means for transmission to a receiver, and a receiver for displaying the image. The displayed image exhibits a second spectral response. The system also has a second reference color means replicating the first spectral response, a comparator for generating a signal responsive to a difference between the replicated first spectral response and the second spectral response and an adjuster for adjusting the displayed image responsive to the signal.

The present invention also provides a method of adjusting a color image transmitted over a network. A color chart exhibiting a first spectral response is illuminated with a light source. An image of the color chart is generated. The image is displayed on a display screen. The displayed image exhibits a second spectral response. A signal responsive to a differential between the first and second spectral responses is generated. The displayed image is modified responsive to the signal.

It is to be understood that both the foregoing general description and the following detailed description are exemplary, but are not restrictive, of the invention.

### BRIEF DESCRIPTION OF THE DRAWING

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1 is a schematic representation of an exemplary embodiment of the invention;

FIG. 2A is a schematic representation of the placement of a color sensor and comparator at an output end of an exemplary embodiment of the invention;

FIG. 2B is a schematic representation illustrating feedback from a color sensor and comparator to a computer in accordance with an exemplary embodiment of the invention;

FIG. 3 is a schematic representation illustrating feedback to the light source in accordance with an exemplary embodiment of the invention;

FIG. 4 illustrates a sample reference signal of an RGB reference color chart;

FIG. 5 illustrates a sample received signal of an image of an RGB reference color chart;

FIG. 6A is a schematic representation of an alternative embodiment of the invention;

FIG. 6B is a flow diagram illustrating controls to adjust video display R, G, B intensities; and

FIG. 7 is a schematic representation of yet another alternative embodiment of the invention.

### DETAILED DESCRIPTION OF THE INVENTION

When images are transmitted over the World Wide Web, global information system, or other network, the final appearance on the viewer's display screen may depend on several components. The components may include the light source that is lighting the scene, such as merchandise or a medical patient, the camera system capturing the image, the transmission medium that transfers the image data, and the computer terminal that displays the image. Each of these sub systems may affect the color appearance of the image. When it is understood how an image transfer occurs and how colors are affected during the transfer, a tunable light source can be used to adjust the colors so that the colors may appear more accurately at the viewer's display.

Products and images of patients have varied appearances when shown under light sources with different spectral power distributions. When someone sees an object directly, the reflected light from the object is detected by the eye and is then processed by the brain for color interpretation. In such a case, there are two major components, namely, the light source and the human visual system. Each component can affect the color appearance of the final image. As an example, if the object is illuminated at different times by two different light sources (e.g., halogen and fluorescent) with very different spectral power distributions (spd), the color appearance of the final image at the different times will be different.

The problem may become worse when an image is captured by a charge-coupled device (CCD) camera, digitized, transferred over the World Wide Web, Internet, or other network, and finally displayed on a remote video display. In such a case, the appearance of the final image may depend on several components, including the light source, the camera system capturing the image, the transmission medium that transfers the image data, and the video terminal that displays the image. Each of these sub-systems may affect the color appearance of the final image.

Therefore, color rendering of the images on the receiving end is an important criterion for web image transfer applications. To obtain good color match between the original object and the final image, it may be important to have identical color gamut between the light source illuminating the original object and the light source used in the video display. In the past, there was no single light source that was suitable for both applications. But now, LED and other solid-state light sources may be used in both applications: illuminating the object and illuminating the video terminal display screen. Therefore, the present invention relates to an LED based lighting system that may be used for web image transfer applications that may seek transfer of good color accuracy from the original object to the final image. In an exemplary embodiment, the lighting system illuminating the object may be same as the lighting system illuminating the video display. In an alternative embodiment, the two lighting systems may be different.

An exemplary embodiment of the invention uses a controllable lighting system that uses multi-spectral LEDs in the visible range. High-brightness colored LEDs may be selected, configured, and controlled to provide optimal color reproduction.

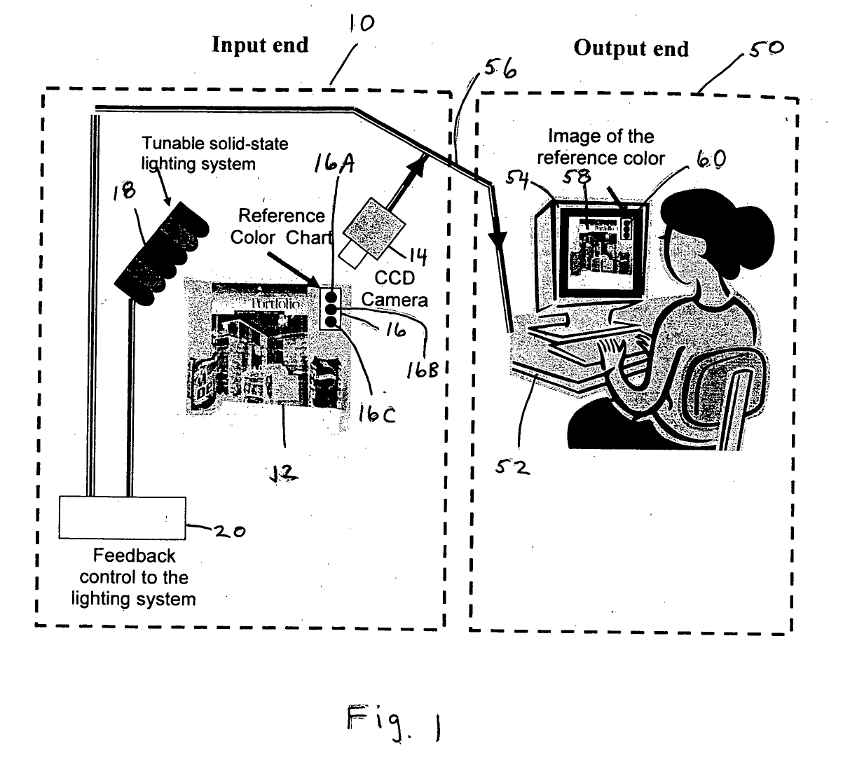

Referring to FIG. 1, there is shown an input end 10 of a network and an output end 50 of the network. The network may be any global information network such as the World Wide Web or the Internet, or it may be any other network such as a local area network (LAN) or intranet. Input end 10 may also be referred to as a transmission end or transmitter. Output end 50 may also be referred to as a receiving end or receiver. Input end 10 shows a photograph 12. Photograph 12 may be a photograph of any object such as a building, merchandise, outdoor scene, indoor scene, person, or animal. The photograph may be a color photograph or a black, white, and gray photograph. Input end 10 also shows a camera 14. In an exemplary embodiment, camera 14 may be a charge coupled device (CCD) camera. In an alternative embodiment, camera 14 may be a video camera with a single CCD or other camera which has three CCD with color filters for more color accuracy. Camera 14 may be positioned so as to enable it to capture images of photograph 12 for transmission to the receiver or output end. Instead of a photograph, camera 14 may also be positioned to observe a patient in a medical facility and to capture images of the patient for transmission to the receiver. Alternatively, camera 14 may be positioned to observe any scene that may be selected by a user of the system.

FIG. 1 also shows a first reference color means 16. In an exemplary embodiment, first reference color means 16 may be a reference color chart. Also in an exemplary embodiment, reference color chart 16 may have three distinct colors placed on it: color 16A may be red; color 16B may be green; and color 16C may be red. Reference color chart 16 may be a standard red, green, blue (RGB) color reference chart. In an alternative embodiment, a reference color chart using colors other than red, green, and blue may be used. In yet another alternative embodiment, reference color chart 16 may display more than three colors or fewer than three colors. In an alternative embodiment, the first reference color means may be a device that provides analog or digital data that is the equivalent of selected colors. For example, a spectrometer apparatus may provide data that are the equivalents of red, green, and blue.

Reference color chart 16 may be placed on or adjacent photograph 12. If an image of a patient is to be transmitted, reference color chart 16 may be placed on or adjacent the patient. Camera 14 may be positioned to capture an image of the photograph 12 alone, the reference color chart 16 alone, or both the photograph and reference color chart simultaneously. In an alternative embodiment where an image of a patient or other object is to be transmitted, camera 14 may be positioned to capture an image of the patient alone or other object alone; the reference color chart alone; or both the patient (or other object) and the color reference chart simultaneously.

FIG. 1 also illustrates a light source 18. Light source 18 may be a color tunable light source such as a solid state light source and may comprise one luminaire, a plurality of luminaires, or an array of luminaires each of which may be tunable. In an exemplary embodiment light source 18 may comprise at least one red light emitting diode (LED), at least one green LED, and at least one blue LED. LEDs may be used in an exemplary embodiment because they are tunable solid-state lighting devices. That is, the intensity of the light from such devices may be increased or decreased by increasing or decreasing the current flowing through them or modulating the current signal in a repetitive manner, known as pulse-width modulation. In an exemplary embodiment, the LEDs may be organic light emitting emitted diodes. In an alternative embodiment, the LEDs may be inorganic light emitting diodes. Light source 18 may direct light onto photograph 12; or, in an alternative embodiment, may direct light onto a patient or, in another alternative embodiment, may direct light onto any other scene selected by a user of the system. At the same time that light from light source 18 may be directed onto the photograph, patient, or scene, the light may also be directed onto reference color chart 16.

FIG. 1 also shows a feedback control 20 coupled to light source 18. The operation of feedback control 20 will be discussed below.

Still referring to FIG. 1, output end 50 of the system is a receiver that is coupled to input end 10. Output end 50 includes a computer 52 and a display screen 54 coupled to computer 52. Images captured by camera 14 may be transmitted to computer 52 and display screen 54 over connection 56. Connection 56 may be a wireless connection over a network such the World Wide Web, the Internet, another global information network, an intranet, or LAN. Connection 56 may also be provided via a wire connection. Images may also be transferred via connection 56 over one or more computer networks. Display screen 54 may display the images. Display screen 54 may be at the same location, or at a different location, as the input end, including a remote location. The images may be displayed on one or more video display screens such as, but not limited to, computer terminals, televisions, and video projections. In an exemplary embodiment, the display screen may have a similar lighting system as the lighting system that is used at the image capture location at the input end. In an alternative embodiment, the display screen may have a different lighting system than the lighting system at the input end.

When camera 14 captures transmitting images of scene 12 and/or reference color chart 16, an image of scene 12 and/or reference color chart 16 may be transmitted to, and displayed on, display screen 54.

More specifically, in an exemplary embodiment, image 58 may be an image of scene 12 and image 60 may be an image of reference color chart 16. In an alternative embodiment, images 58 and 60 may be located at other positions on the display screen and their relative sizes may be different than what is illustrated in FIG. 1. Images 58 and 60, however, may not exhibit the identical color characteristics as the original scene 12 and the original reference color chart 16. The color characteristics of the images may have been degraded relative to the characteristics of the original colors in reference color chart 16 due to losses caused by the camera system, the transmission medium that transfers the image data, the computer terminal that receives the images, and the display screen that displays the images.

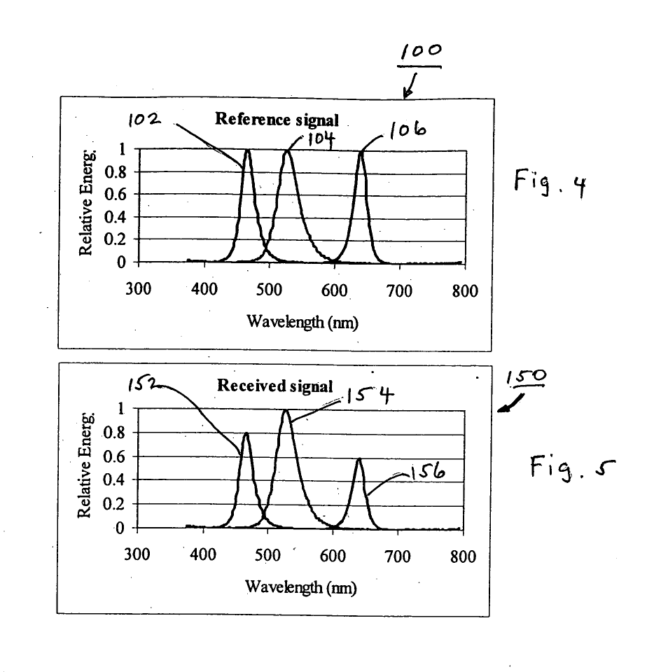

A spectral response of a color may be defined in terms of its wavelength and the intensity of the energy it emits. Intensity may be measured by the amplitude of the spectrum. FIG. 4 illustrates a sample reference signal exhibiting a sample spectral response of the RGB reference color chart 16 shown in FIG. 1. FIG. 4 is a sample plot of colors exhibiting three wavelengths and the relative intensity of each color represented by each of the wavelengths. Curve 102 illustrates a curve for a sample blue color; curve 104 illustrates a curve for a sample green color; and curve 106 illustrates a curve for a sample red color. The relative intensity, or amplitude, of each color is represented by the vertical axis in FIG. 4. In an exemplary embodiment, the relative intensity of each color may be the same, as illustrated in FIG. 4. In an alternative embodiment, the intensity of some or all of the colors in the reference color chart may not be the same.

FIG. 5 illustrates a sample received signal of an image of the reference color chart. More specifically, FIG. 5 illustrates a spectral response of the colors of image 60 that may be displayed on display screen 54 at output end 50. In the exemplary embodiment illustrated in FIG. 5, the relative amplitude of sample blue color 152 is 0.8, the relative amplitude of sample green color 154 is 1.0, and the relative amplitude of sample red color 156 is 0.6. In an alternative embodiment, the relative amplitudes of each color may be different than the relative amplitudes illustrated in FIG. 5. As explained above, differences in relative amplitudes may be caused by the components of the system.

The invention compares the spectral response of the received signal 150 with the spectral response of the reference signal 100 in order to bring the spectral response of the received signal 150 closer to the spectral response of the reference signal 100. As the spectral responses become closer, the image 60 of reference color chart may appear more like reference color chart 16 and the image 58 of scene 12 may appear more like scene 12.

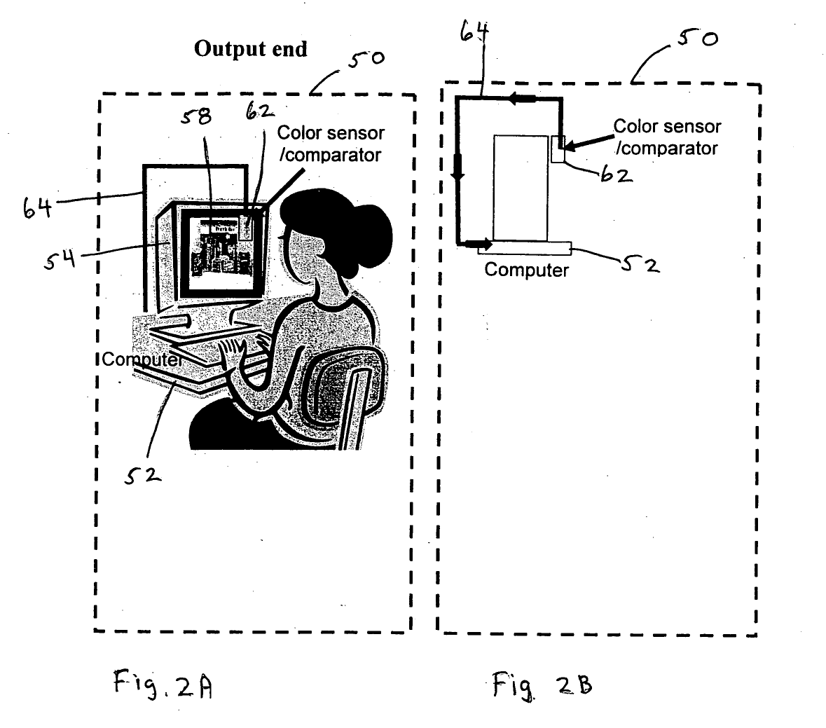

Referring to FIGS. 2A and 2B, output end 50 is shown. In FIG. 2A, an image 58 of scene 12 is illustrated on display screen 54. Image 60 of reference color chart is not shown because in the exemplary embodiment, it may be covered by a device 62 which may contain a color sensor and a comparator. In an exemplary embodiment, device 62 may be a spectrometer. In an alternative embodiment, device 62 may be any device that is capable of measuring the spectral response of image 60. That is, device 62 may be any device that is capable of measuring the spectrum and the amplitude of each color in image 60. In an exemplary embodiment, device 62 may be a spectrometer or other color sensor system that may be attached to the video terminal close to the surface of display screen 54 where image 60 is located.

Device 62 may contain a number of conventional sub-systems (not shown). First, it may contain a second reference color means that replicates the first spectral response of the first reference color means. In an exemplary embodiment, device 62 may contain a chip that is preprogrammed to digitally replicate the spectral response of reference color chart 16. Accordingly, the spectral response of reference color chart 16 may be the same as the spectral response that is preprogrammed onto the chip located in device 62. In an exemplary embodiment, the spectral response of reference color chart 16 and the preprogrammed spectral response on the chip in device 62 may both be represented by the reference signal 100 illustrated in FIG. 4. In an alternative embodiment, the two spectral responses may both be represented by a reference signal exhibiting a spectral response that is not the same as the spectral response exhibited in FIG. 4. A significant criterion about the spectral response of the reference signal may be that the spectral response of the reference color chart 16 may be substantially the same as the spectral response of the preprogrammed chip in device 62.

Second, device 62 may have a sensor that senses the spectral response of image 60 and provides a signal representative of the spectral response of image 60. In an exemplary embodiment, the representative signal may be a digital signal. In an alternative embodiment, the representative signal may be an analog signal which may then be converted into a digital signal with an analog-to-digital converter.

Third, device 62 may have a comparator that compares the replicated reference signal with the spectral response of image 60 that is sensed by the sensor in device 62. That is, the comparator may compare the spectrum (wavelengths and the corresponding energy at each wavelength) of the original reference color chart with the spectrum (wavelengths and corresponding energy at each wavelength) of its image on the display screen.

The comparator may divide the spectral response of image 60 by the reference spectral response in order to obtain the amount of color distortion in each channel of the RGB signals. The comparison may generate a signal 64 that is responsive to the difference between the replicated first spectral response and the second spectral response of the image 60. More specifically, in an exemplary embodiment, signal 64 may have three components. One component of signal 64 may represent the difference between sample blue spectral response 102 and sample blue spectral response 152. A second component of signal 64 may represent the difference between sample green spectral response 104 and exemplary green spectral response 154. A third component of signal 64 may represent the difference between sample red spectral response 106 and sample red spectral response 156. In an alternative embodiment, where a reference color chart exhibits different spectral responses than those shown in FIG. 4 or exhibits spectral responses of more or fewer than three colors, signal 64 may represent differences for the various spectral responses and/or for each of the colors, thus corresponding to the number of colors in the reference color chart.

The signal 64 may be transmitted over a feedback circuit to various parts of the system. Part of the feedback circuit may transmit signal 64 to computer 52 which has a microprocessor. After the signal 64 is transmitted to computer 52, the microprocessor in the computer may be used as an adjuster to adjust the displayed image of the color reference chart response to signal 64. More specifically, responsive to signal 64, the microprocessor in computer 52 may adjust the RGB spectrum of image 60. The adjustment may be performed in at least one of two ways.

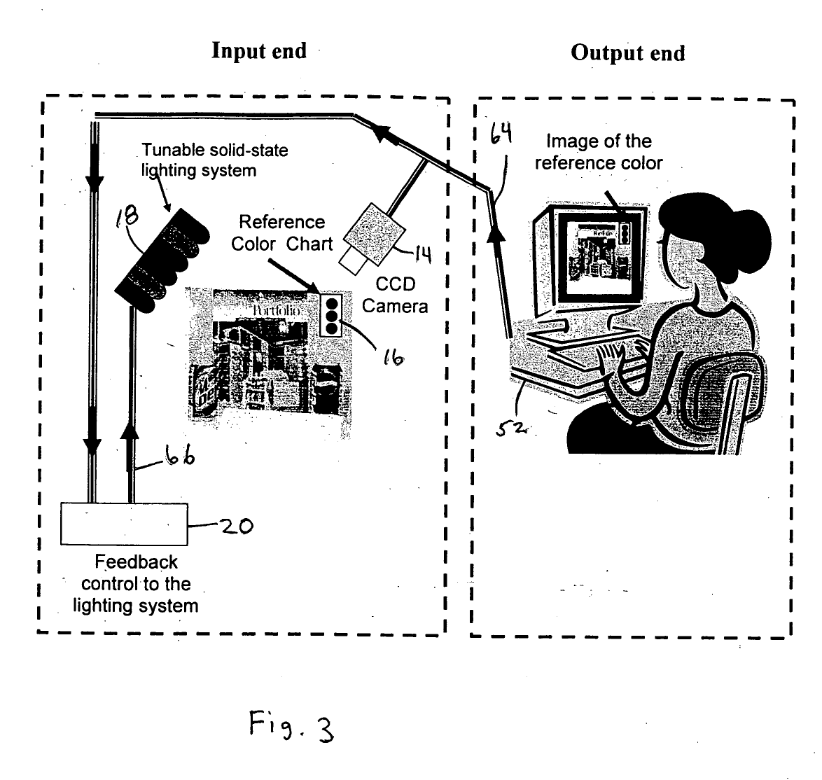

In an exemplary embodiment, FIG. 3 illustrates that in another part of the feedback circuit, signal 64 may be transmitted from computer 52 to feedback control 20. Feedback control 20 may be an electronic board that contains circuits which operate to provide adjusting signals to the LEDs. Feedback control 20 may include adjusters that may transmit one or more adjusting signals 66 to LED array 18. Adjusting signal or signals 66 may change the current flowing to one or more individual solid state light sources, i.e., to one or more LEDs in LED array 18. Increasing the current flowing to a particular LED may increase the amplitude, and therefore the intensity, of light emanating from the LED. That is, increasing the intensity of an LED may increase the intensity of that particular color light source. Conversely, decreasing the current flowing to a particular LED may decrease the amplitude, and therefore the intensity, of light emanating from the LED. That is, decreasing the intensity of an LED may decrease the intensity of that particular color light source.

In an exemplary embodiment, signals 66 may cause an increase in the intensity of one or more blue LEDs in LED array 18, may not cause an increase in the intensity of one or more green LEDs in LED array 18, and may cause an increase in the intensity of one or more red LEDs in LED array 18. In alternative embodiments, the intensities of different combinations of LEDs may be implemented by the system responsive to signal 66. As the intensities of LEDs in LED array 18 are being modified, LED 18 array may continue to illuminate scene 12 and reference color chart 16. Furthermore, as signals 66 modify the intensities of one or more LEDs in LED array 18, camera 14 may capture images of scene 12 and reference color chart as illuminated by modified intensities of the LEDs. The modified intensities may generate one or more modified signals 56.

Signal 56, as modified, may transfer a modified image of reference color chart 16 responsive to light from LED array 18 being transmitted at a different intensity. Consequently, the spectral response of the image of color reference chart 16 may be modified by the modification of the intensity of LED array 18. The new image may then be compared with the reference signal stored in device 62 resulting in a new differential signal 64 being sent to feedback control 20. Signals 56 and 64 may be repetitively sent to and from display screen 54 in a repetitive, iterative process in a repetitive attempt to bring the spectrum of the received signal as close as possible to the spectrum of the reference signal.

In an alternative embodiment, signal 64 may be transmitted from the microprocessor in computer 52 back to the display screen. Where the display screen is comprised of one or more LEDs, signal 64 may control the intensity of one or more LEDs in the display screen via a feedback control. In this embodiment, the intensity of the LEDs in the display screen may be modified in order to enable the spectrum of the received signal to become closer to the spectrum of the reference signal. In another embodiment, signal 64 may be transmitted back to display screen 54 where the display screen is not comprised of one or more LEDs. In such an embodiment, a signal attenuator may be used to modify the intensity of the image exhibited on the display screen. These alternative embodiments may be useful, for example, when the scene being illuminated is an operating room in a medical facility. In an operating room, it may not be practicable to adjust the intensity of the lights because the operating room personnel may need the lighting to remain at a fixed intensity. Under such circumstances, it may be more practicable to adjust the intensity of the image on a remote display screen.

In yet another embodiment, light array 18 may not be comprised of LEDs. Instead, light array 18 may be comprised of incandescent, fluorescent, or halogen luminaires or other luminaire. When alternative luminaires are used, adjustable color filters may be placed between the luminaires and the scene 12 and between the luminaires and color reference chart 16. In such an embodiment, signals 64 and 66 may adjust the amount of light that is filtered by the filters in order to adjust the intensity of light of the various colors that illuminate the color reference chart. In an exemplary embodiment, the filters may be made of plastic or glass.

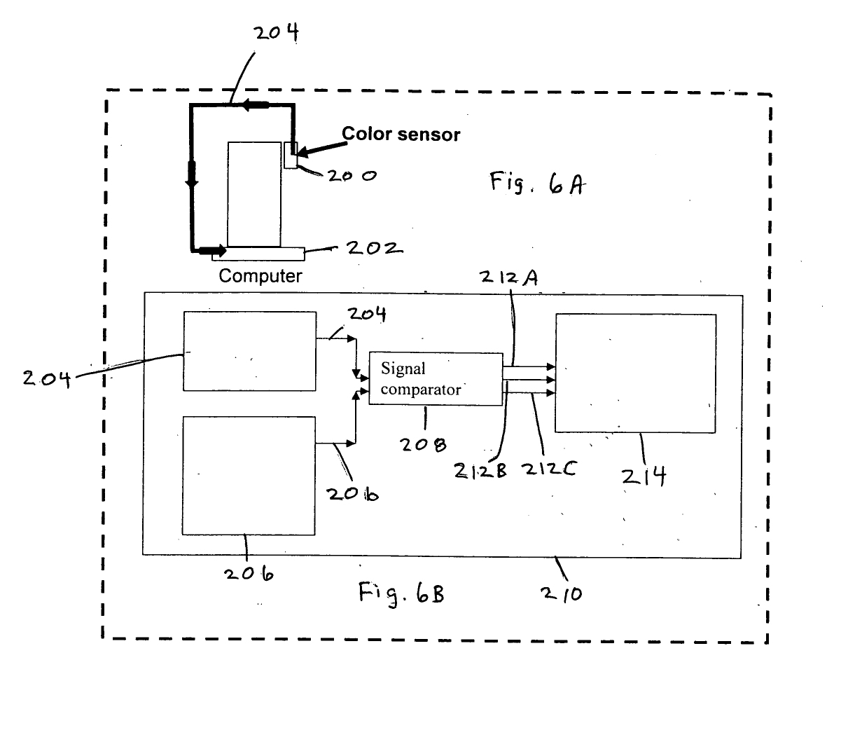

FIG. 6A is a schematic representation of an alternative embodiment of the invention. In this embodiment, color sensor 200 may be attached over the transferred image of the color reference chart. Again, color sensor may be a spectrometer. But, in this embodiment, it may not include a comparator. Color sensor 200 may sense the spectral response of the transferred image and may provide a signal 204 representative of the spectral response of the transferred image. In this alternative embodiment, the representative signal 204 may be a digital signal or it may be an analog signal which may then be converted into a digital signal with an analog-to-digital converter. Signal 204 may contain each channel of the RGB signals and may be transferred to computer 202.

FIG. 6B is a flow diagram illustrating an apparatus and method to adjust the video display R, G, B intensities at a display screen such as a video display, computer terminals, televisions, and video projections. Referring to FIG. 6B, digital electronics board 210 may be located within computer 202 at the display end of the system. RGB signal 204 may be transferred to a signal comparator 208. A memory in the microprocessor of computer 202 or elsewhere may supply a reference RGB signal 206 to the signal comparator 208. Reference RGB signal 206 may exhibit a spectral response that replicates the spectral response of the reference color chart.

Signal comparator 208 may compare the spectral response of reference RGB signal 206 with the spectral response of RGB signal 204. The comparator may divide the spectral response carried by signal 204 by the reference RGB signal 206 in order to obtain the amount of color distortion in each channel of the RGB signals. The comparison generates RGB signals 212A, 212B, and 212C that are responsive to the difference between the spectral response of the replicated reference signal 206 and the spectral response of signal 204. More specifically, in this alternative embodiment, as in other embodiments, the signal representing the result of the signal comparison may have three components. One component may represent a difference between the spectral response of the blue channel of signal 206 and the spectral response of the blue channel of signal 204. A second component may represent a difference between the spectral response of the green channel of signal 206 and the spectral response of the green channel of signal 206. A third component may represent a difference between the spectral response of the red channel of signal 204 and the spectral response of the red channel of signal 206. In another alternative embodiment, where a reference color chart exhibits more or fewer than three colors, the signals transmitted from signal comparator 208 may have more or fewer channels corresponding to the number of colors in the reference color chart.

RBG signals 212A, 212B, 22C may be transferred from signal comparator 208 to a video display 214. In this alternative embodiment, video display 214 may comprise one or more LEDs and may use an LED driver controller (not shown), coupled to video display to adjust the intensities of the LEDs. Accordingly, RGB signals may be transferred to the LED driver controller. RGB signals 212A, 212B, 212C may cause the LED driver controller to change the current flowing to one or more of the LEDs thereby changing the intensity of some or all of the respective LEDs.

As RGB signals 212A, 212B, 212C cause changes in LED intensities, new comparisons may be made via color sensor 200 and signal comparator 208. Signals 204 with varying spectral responses may be sent to signal comparator 208 causing new RGB signals 212A, 212B, 212C to be sent to video display 214 in a repetitive, iterative process in an attempt to bring the spectrum of the received signal as close as possible to the spectrum of the reference signal 206.

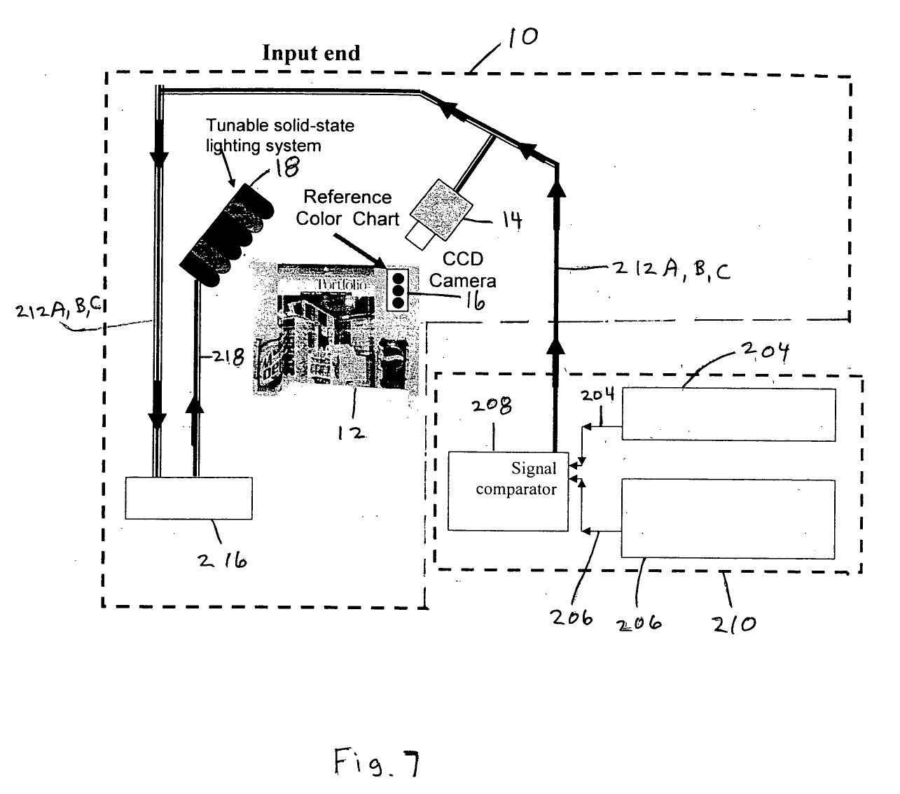

FIG. 7 is a schematic representation of yet another alternative embodiment of the invention. More specifically, FIG. 7 illustrates an apparatus and method of adjusting the intensities of the LEDs of light source 18 at input end 10. Similar to FIG. 6B, FIG. 7 illustrates RGB signal 204 that may be transferred from color sensor 200 to a signal comparator 208. FIG. 7 also illustrates reference RGB signal 206 being transferred to signal comparator 208. Signal comparator 208 performs the same comparisons described in connection with FIG. 6B resulting in RGB signals 212A, 212B, and 212C.

Still referring to FIG. 7, RGB signals 212A, 212B, 212C may be transferred from signal comparator 208 to a driver 216 coupled to light source 18. In response to RGB signals 212A, 212B, 212C, driver 216 may transfer one or more driver control signals 218 to light source 18. In this alternative embodiment, when light source 18 comprises a plurality of LEDs, driver 216 may be an LED driver. Driver control signals 218 may adjust the intensities of the LEDs that comprise light source 18 by changing the current flowing to one or more of the LEDs.

As control signals 218 cause changes in LED intensities, new comparisons may be made via color sensor 200 and signal comparator 208. Signals 204 with varying spectral responses may be sent to comparator 208 causing new RGB signals 212A, 212B, 212C to be sent to driver 216 in a repetitive, iterative process in an attempt to bring the spectrum of the received signal as close as possible to the spectrum of the reference signal 206.

Although the invention is illustrated and described herein with reference to specific embodiments, the invention is not intended to be limited to the details shown. Rather, various modifications may be made in the details within the scope and range of equivalents of the claims and without departing from the invention.

1. A system for transmitting a color image over a network, the system comprising:
a light source;
a first reference color means exhibiting a first spectral response;
a camera capturing an image of the first reference color means for transmission to a receiver;
a receiver for displaying the image, the displayed image exhibiting a second spectral response;
a second reference color means replicating the first spectral response;
a comparator for generating a signal responsive to a difference between the replicated first spectral response and the second spectral response; and
an adjuster for adjusting the displayed image responsive to the signal.

2. The system of claim 1, wherein the light source is an adjustable light source.

3. The system of claim 2, wherein the adjustable light source is a light emitting diode.

4. The system of claim 2, wherein the adjustable light source comprises a plurality of light emitting diodes.

5. The system of claim 1, wherein the light source is a color tunable light source.

6. The system of claim 5, wherein the color tunable light source includes at least one red light source, one green light source, and one blue light source.

7. The system of claim 1, wherein the first reference color means includes a color chart.

8. The system of claim 1, wherein the adjuster includes a feedback circuit between the receiver and the light source.

9. The system of claim 1, wherein the comparator includes a sensor for measuring an intensity of the second spectral response.

10. The system of claim 1, where the comparator includes a color sensor system for measuring a spectrum of the displayed image.

11. The system of claim 1, wherein the receiver comprises a display screen having at least one light emitting diode.

12. The system of claim 1, wherein the adjuster includes a circuit for adjusting the displayed image in an iterative manner.

13. An illumination system comprising:
a reference color chart having a first spectral response;
a plurality of solid state light sources for illuminating the reference color chart, each solid state light source providing visible light at a preselected intensity;
a camera capturing at least one image of the reference color chart for transmission to a display screen;
a display screen for displaying the image of the reference color chart, the image exhibiting a second spectral response; and
an adjuster configured to adjust the displayed image responsive to a difference between the first spectral response and the second spectral response.

14. The illumination system of claim 13, wherein each of the solid state light sources is a light emitting diode.

15. The illumination system of claim 14, wherein at least one light emitting diode is an organic light emitting diode.

16. The illumination system of claim 14, wherein at least one light emitting diode is an inorganic light emitting diode.

17. The system of claim 13, wherein the reference color chart exhibits a plurality of colors.

18. The system of claim 13, wherein the adjuster is coupled to the plurality of solid state light sources for adjusting an intensity of at least one of the solid state light sources.

19. The system of claim 13, wherein the adjuster is coupled to the display screen for adjusting an intensity of the display screen.

20. The system of claim 13, wherein the adjuster includes a sensor for measuring a spectrum of the image and a feedback circuit from the sensor to the display screen for adjusting an intensity of the image.

21. The system of claim 20, further comprising a comparator coupled to the sensor for comparing the first spectral response with the second spectral response.

22. The system of claim 20, wherein the display screen includes at least one light emitting diode and the feedback circuit is coupled to the at least one light emitting diode.

23. A method of adjusting illumination of a scene by a light source, the method comprising the steps of:
illuminating a color chart adjacent the scene, the color chart exhibiting a first spectral response with the light source;
capturing an image of the illuminated color chart;
displaying the image on a display screen, the displayed image exhibiting a second spectral response;
generating a signal responsive to a difference between the first and second spectral responses; and
adjusting the illumination of the scene by the light source responsive to the signal.

24. A method of adjusting a color image of a scene transmitted over a network, the method comprising the steps of:
illuminating a color chart adjacent the scene with a light source, the color chart exhibiting a first spectral response;
capturing an image of the illuminated color chart;
displaying the image on a display screen, the displayed image exhibiting a second spectral response;
generating a signal responsive to a difference between the first and second spectral responses; and
adjusting the displayed image responsive to the signal.
